(19) United States
(12) Patent Application Publication
(10) Pub. No.: US 2022/0154340 A1
(43) Pub. Date: May 19, 2022

(54) APPARATUS AND METHOD FOR VACUUM COATING SURFACES OF OBJECTS

(71) Applicant: KHS GMBH, Dortmund (DE)

(72) Inventors: Michael HERBORT, Hamburg (DE); Jan LENGEFELD, Bönebüttel (DE); Patrick HEIDEMANN, Ratzeburg (DE)

(21) Appl. No.: 17/441,147

(22) PCT Filed: Mar. 13, 2020
(86) PCT No.: PCT/EP2020/056748

§ 371 Date: Sep. 20, 2021

(30) Foreign Application Priority Data
Mar. 21, 2019 (DE) 10 2019 107 237.9

(51) Int. Cl. C23C 16/52; C23C 14/24; C23C 16/44; C23C 14/54; C23C 14/56; C23C 16/455

(52) U.S. Cl. CPC C23C 16/52; C23C 14/24; C23C 16/455; C23C 14/542; C23C 14/564; C23C 16/4401

(57) ABSTRACT

An apparatus for coating surfaces of objects by a gas deposition method under vacuum conditions in process chambers, including at least one treatment chamber for receiving the objects to be coated and at least one additional process chamber, connected to the at least one treatment chamber, for conducting gases to be deposited and/or discharging portions of non-deposited partial gas quantities. A measuring unit for detecting the coating thickness on a surface or sections of the surface of the process chambers is arranged in at least one additional process chamber. The measuring unit is connectable to a control and evaluation unit. The measuring unit detects ACTUAL data of the coating thickness on a surface of the at least one additional process chamber as measured value and these ACTUAL data are forwarded to an evaluation device, in which these ACTUAL data are compared with NOMINAL data.

### FIELD OF INVENTION

The present invention relates to an apparatus for coating surfaces of objects by means of a gas deposition method under a vacuum provided by a vacuum system, said apparatus having process chambers, including a treatment chamber for receiving the objects to be coated, in particular the interior surfaces of hollow bodies, such as drinks containers, and process chambers, connected to the treatment chamber, for providing gases/gas mixtures to be deposited. Furthermore, the invention relates to a corresponding method for monitoring coating apparatuses and in particular the interior surfaces of their gas compartments/pipelines.

For example, PVD, CVD, PCVD come into consideration as gas deposition methods for the coating apparatus.

### BACKGROUND OF RELATED ART

In the coating process, not all reactive constituents in the coating chamber and on the surface to be coated of the objects provided for the coating are converted. Inside the vacuum system this activated residual gas mixture coats components of the coating apparatus, such as for instance pumps, pipes, flappers, etc., in an undesired manner. The degree of the undesired coating is dependent on the surface geometry and the container shape (bottle) of the object to be coated and the formula used.

Until now, maintenance intervals, in which the surfaces of the components and process chambers of the coating apparatus are cleaned, have been derived from empirical values, without taking the actual contamination by undesired coating into account. In case of doubt, no prediction is possible at all and the system has to be serviced and cleaned at a very early stage or run until an unexpected stoppage.

This is a great disadvantage and an element of uncertainty in particular in the case of coating systems with highly or frequently varying formulae for gas mixtures.

### SUMMARY

There is therefore a need to determine the necessity of maintenance, associated with the removal of undesired coatings, of coating apparatuses of the type named at the start without the necessity of having to deactivate and inspect the entire apparatus.

An object of the present invention is therefore to develop a coating apparatus of the type named at the start which guarantees the determination of the necessity of maintenance, associated with the removal of undesired coatings, of the coating apparatus without the necessity of having to deactivate the entire apparatus.

This object is achieved according to the invention by the features of the independent claims. Advantageous embodiments are specified in the dependent claims.

The invention therefore provides an apparatus for coating surfaces of objects by means of a gas deposition method under a vacuum provided by a vacuum system, said apparatus having process chambers, including at least one treatment chamber for receiving the objects to be coated and at least one additional process chamber, connected to the at least one treatment chamber, for conducting gases to be deposited and/or discharging portions of non-deposited partial gas quantities. A measuring unit for detecting the coating thickness on a surface or on sections of the surface of the process chambers is arranged in at least one additional process chamber, wherein the measuring unit is connectable to a control and evaluation unit. The control and evaluation unit is preferably equipped to determine the necessity and/or the time for cleaning the surfaces of the at least one additional process chamber or the treatment chamber by removing undesired coating. The control and evaluation unit is particularly preferably equipped to evaluate an ACTUAL degree of coverage or progression of an ACTUAL degree of coverage, in particular with respect to a NOMINAL degree of coverage or NOMINAL progression of a degree of coverage.

In the present case, any interior of the apparatus which is at least at times acted on by a vacuum during normal operation and into which the gas to be deposited is conducted is to be regarded as process chamber. Thus, in particular, the actual treatment chamber in which at least one object can be coated and the vacuum lines attached to it which are connected to one or more vacuum pumps in order to set the process pressure needed (vacuum) and/or to conduct gases are preferably regarded as process chamber.

The surfaces to be coated of objects are preferably interior surfaces of hollow bodies, such as for example containers, in particular bottles, preferably plastic bottles. The apparatus is particularly preferably equipped to coat interior walls of bottles, in particular PET bottles.

A gas deposition method is e.g., a PVD (Physical Vapour Deposition), a CVD (Chemical Vapour Deposition) or a PCVD (Plasma (assisted) Chemical Vapour Deposition) method. These methods are carried out under vacuum.

The gases that can be provided in the connected process chambers can be gases or gas mixtures. By gases is meant here gases consisting of one chemical compound or one chemical element. Gas mixtures are gases consisting of at least two different chemical elements or chemical compounds. In the present case, a vapour phase is also synonymously called a gas, unless something different is explicitly mentioned. Gas mixtures are preferably also homogeneous substance mixture.

The deposition rate is preferably measured during operation and thereby allows a prediction about the degree of contamination of individual components without opening the vacuum system.

Furthermore, the present invention guarantees a long-term inline measurement of undesired coating. A meaningful prediction of the maintenance interval of process pumps, flappers (butterfly valves), vacuum pipework etc. is thereby guaranteed. The remaining lifetime (until maintenance) can thereby be constantly matched with the planned lifetime and, where appropriate, currently unnecessary maintenance activities are even identified and skipped over or delayed.

Finally, through the monitoring, according to the invention, of the deposition rate of the undesired deposition, the efficiency of the coating apparatus is increased, as it can be predicted when the state of maximum tolerable stress will be reached. It is thereby also guaranteed that unplanned outages can be avoided.

It is advantageously provided to arrange the measuring unit in an area of the additional process chambers which is accessible without having to open the entire vacuum system of the coating apparatus.

An apparatus is preferably provided in which the measuring unit is arranged in a bypass, in a separable chamber or line section, in a vacuum line of the vacuum system, in a supply line to the treatment chamber or in a discharge line from the treatment chamber.

This location, at which the measuring unit is arranged, is preferably isolatable, with the result that the measuring unit or the sensor element can be replaced during operation. This is preferably achieved by valves at both ends or on both sides and suitable opening/removal measures which guarantee that the entire vacuum system need not be opened.

Other locations of the coating system suitable for this purpose can be taken into consideration, preferably as long as it is guaranteed that the measuring unit is accessible there without having to open the entire vacuum system of the coating apparatus.

The measuring unit being used according to the invention preferably comprises a coating thickness detection element, which has a sensor section, and the sensor section comprises a strain measuring strip and/or resistance measuring strip and/or capacitive sensor measuring strip and/or magnetic induction measuring strip. All sensors of different construction are preferably suitable for this element, in particular if they are miniaturized to the extent that they can be used at suitable locations or areas of the coating apparatus without requiring more space. These preferably include sensors for measuring layer thicknesses of non-metallic coatings on metallic substrate according to the magnetic induction principle and sensors which use the eddy current principle to measure insulating layers on non-ferrous metals (coating on metallic carrier material). In the present case, coating thickness sensors or detection elements which can be produced in strip form, such as for instance strain measuring strips, resistance measuring strips, capacitive sensor measuring strips and/or magnetic induction measuring strips, are particularly suitable. The measuring unit is particularly preferably a gravimetric measuring unit, i.e., a measuring unit which takes the weight difference of the deposit, in particular on the sensor of the measuring unit, into account.

In a further embodiment the measuring unit comprises a carrier and seal section and a sensor section, wherein the sensor section can be non-destructively connected to and releasably combined with the carrier and seal section. The sensor section is preferably formed pluggable. It is thereby possible to remove the sensor section alone for evaluation and to replace it with a new one without having to replace the entire measuring unit.

In a further embodiment the sensor section has a measuring tongue and an interface section, via which the connection to the carrier and seal section can be established. Thus, it is possible to have to remove only an interface section connected to the measuring tongue when the sensor section is removed, and not further elements of the measuring unit.

In a further embodiment an apparatus is provided, in which the measuring unit has a transponder, with which data and/or signals can be transmitted from the control and evaluation unit wirelessly to a receiving station. Such a transponder can preferably be a radio transmitter or based on RFID technology.

In a further embodiment an apparatus is provided, in which the measuring unit protrudes into a pipeline of the vacuum system. Through the measurement in a pipeline of the vacuum system, a critical part of the coating apparatus is monitored.

A measuring unit which comprises a carrier for the preferably strip-shaped coating thickness detection element which is attached to a vacuum feedthrough, wherein the vacuum feedthrough can be connected to a flange pipe which opens into a hole in the wall of the at least one additional process chamber, and wherein the coating thickness detection element comes to rest in the area of the hole, is particularly advantageous.

The object of the present invention is also achieved by a method for monitoring surfaces in line paths of an apparatus according to the invention for coating surfaces of objects in which the measuring unit detects ACTUAL data of the coating thickness on a surface of the at least one additional process chamber as measured value and these ACTUAL data are forwarded to an evaluation device, in which these ACTUAL data are compared with NOMINAL data.

In the process, the measuring unit detects ACTUAL data as measured values depending on the sensor used. These measured values allow a conclusion to be drawn as to the coating thickness in the area in which the measuring unit is used, and thus as to the neighbouring lines or process chambers.

The NOMINAL data are preferably predefined and correspond to the measured values or the coating thicknesses derived therefrom. The NOMINAL data are preferably predefinable and can preferably also be adjusted. An adjustment can preferably be effected depending on chosen formulae, downtimes, working times or empirical values from measuring units run in parallel, either in the same apparatus or in an apparatus run in parallel.

The evaluation unit preferably comprises a comparator, with which the ACTUAL data and the NOMINAL data are compared with each other. The ACTUAL data also preferably comprise a time stamp, with the result that a gradient over time can be determined from the quantity of ACTUAL data determined. This can be used to predict future coating scenarios.

The comparison of the ACTUAL data with the NOMINAL data is preferably effected continuously or sequentially. To measure the coating thickness in systems which are running, it can preferably be sufficient to carry out a comparison daily. The interval in which the comparison is effected is preferably predetermined depending on the gradient of the ACTUAL data determined in the past. Thus, it is possible in the case of a freshly cleaned apparatus to perform a comparison in three days, while in the case of a gradient which makes it appear possible that the NOMINAL data will soon be reached a smaller interval is predefined.

The comparison of the ACTUAL data with the NOMINAL data is particularly preferably effected continuously and is delivered wirelessly to an evaluation unit and continuously evaluated there. The development of the ACTUAL data over time is particularly preferably correlated to the coating processes run on the apparatus. It is thereby possible to identify particularly critical methods in which a steeper gradient of the ACTUAL data occurs than in other methods. This knowledge can be utilized to predict the coating thickness when taking into account the coating processes to be run on the apparatus in the future.

In the case of predetermined configurations, a signal with which a message, in particular a fault report or a warning message, is generated is preferably produced when the ACTUAL data and the NOMINAL data are compared. This configuration can preferably be freely defined and selected for predetermined coating thicknesses, such as for example 80% of the maximum achievable coating thickness before a cleaning operation for a warning message or 95% for a fault report.

Maintenance and/or shutdown times are preferably predicted and preferably also notified depending on the gradient of the measured value over time.

Preferably, measurements are taken at several locations and messages about the need for maintenance and/or cleaning are notified by section and/or a shutdown is predicted. The measurement at several locations in the apparatus makes it possible to take the coating situation at several selected locations into account and compare them with each other. Thus, a more accurate picture of the coating situation is determined and individual (partially) defective measuring units or sensor elements are compensated for by redundancy and also identified. Moreover, the susceptibility to coatings can be different at the different locations and this difference can also be determined and utilized for the prediction.

The measuring unit, in particular the sensor section, is preferably removed and evaluated outside the apparatus for coating surfaces of objects. Because the sensor element is simply plugged in and unplugged, it is possible to replace it and to read the loaded sensor element externally. The old, loaded sensor element is particularly preferably then refurbished in order to be able to be re-used.

### BRIEF DESCRIPTION OF THE DRAWINGS

Further details and advantages of the invention will now be explained in more detail with reference to an embodiment represented in the drawings.

There are shown in:

FIG. 1—a double coating chamber for containers as well as the supplying and discharging vacuum and gas lines,

FIG. 2—a sectional view of a pipeline section of the coating apparatus according to the invention, in which a measuring unit is arranged, and

FIG. 3—a top view of an embodiment of the measuring unit in the pipeline section of FIG. 2.

### DETAILED DESCRIPTION

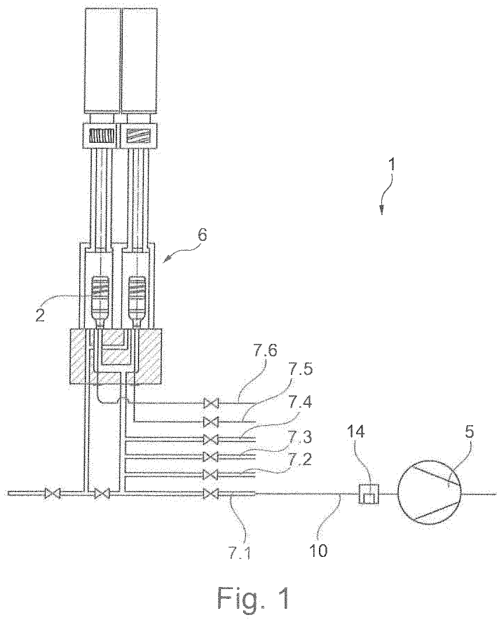

The coating apparatus 1 shown in FIG. 1 shows a double coating chamber 6 for containers 2 as well as supplying and discharging vacuum and gas lines 7.1 to 7.6. A pipeline section 10, in which a measuring unit 14 is arranged, is shown in front of a vacuum pump 5 in the discharging line 7.1.

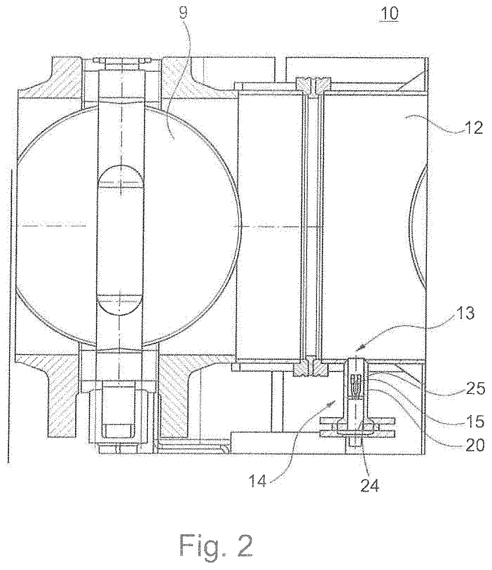

This pipeline section 10 from FIG. 1 is shown again in more detail in FIG. 2. The pipeline section 10 of the apparatus for coating surfaces of objects by means of a gas deposition method under a vacuum provided by a vacuum system has an additional process chamber 12 in the form of a pipeline with measurement connections for receiving a measuring unit 14. A flap valve or flapper 9 (represented to the left of the additional process chamber 12) is connected to this additional process chamber 12. The vacuum pump 5 is attached on the other side (to the right of the additional process chamber 12—not shown here).

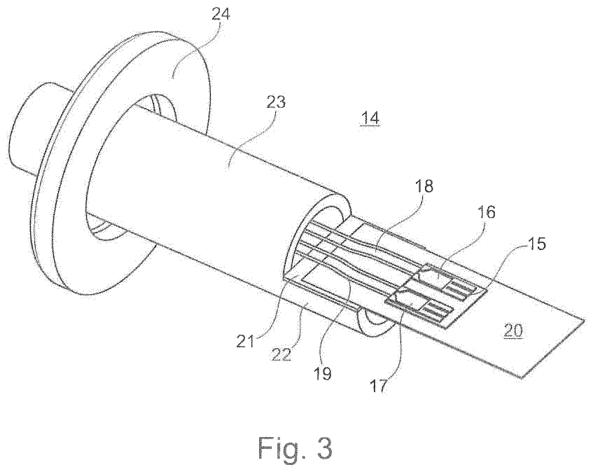

Attached to a wall of the additional process chamber 12 is a measuring unit 14, which is shown in greater detail in FIG. 3, communicating with the interior thereof via a hole 13. This measuring unit 14 is preferably a gravimetric measuring unit. The measuring unit 14 is used for the (preferably gravimetric) detection of the coating thickness on the surface of the process chamber 12 in the area of the hole 13. In a manner not shown in FIG. 2, the measuring unit 14 is connected to a control and evaluation unit for determining the need to clean the surfaces of the process chambers or parts thereof by removing undesired coating.

As can be seen from FIG. 3, the measuring unit 14 comprises a strip-shaped coating thickness detection element 15 in the form of a strain measuring strip which has two sensor panels 16 and 17, the output signals of which are connected to the control and evaluation unit via in each case two measuring line pairs 18 and 19. The strain measuring strip 15 is attached to a flat sheet element 20, which is mounted over a base plate 21 made of insulating material, which is fixed on an axially cut-open pipe end part 22 of a tubular carrier 23. The two measuring line pairs 16 and 17 pass through the tubular carrier 23 and are guided out of it via a vacuum feedthrough 24.

As can be seen from FIG. 2, the measuring unit 14 is coupled to the additional process chamber 12 via a flange pipe 25 connected in a vacuum-tight manner to the wall of the additional process chamber 12 in such a way that its detection element 15 comes to rest in the area of the hole 13, but set back from the wall of the additional process chamber 12, in order to determine the thickness of an undesired coating on the surface of the additional process chamber 12 at this location.

Through the measurement of the coating thickness, the state of the vacuum components can be monitored constantly or continuously (dynamically) during the running maintenance interval. The remaining lifetime (until maintenance) can thus be constantly matched with the planned lifetime and, where appropriate, currently unnecessary maintenance activities are even identified and skipped over or delayed.

The efficiency of the systems is increased by the present invention, as it can thereby be predicted when the state of maximum tolerable stress will be reached, and thus unplanned outages are avoided.

### LIST OF REFERENCE NUMBERS

1 coating apparatus
2 bottle, hollow body
5 vacuum pump
6 double coating chamber for containers
7 supplying and discharging vacuum and gas lines
9 flap valve or flapper (butterfly valve)
pipeline section
12 additional process chamber (e.g. pipe section with measurement connections)
13 hole
14 measuring unit coating thickness detection element
16 sensor panel
17 sensor panel
18 measuring line pair
19 measuring line pair
20 sheet element
21 base plate
22 pipe end part
23 carrier
24 vacuum feedthrough
25 flange pipe

1. An apparatus for coating surfaces of objects by means of a gas deposition method tinder a vacuum provided by a vacuum system, said apparatus having process chambers (12), including at least one treatment chamber for receiving the objects to be coated and at least one additional process chamber (12), connected to the at least one treatment chamber, for conducting gases to be deposited and/or discharging portions of non-deposited partial gas quantities,
wherein a measuring unit (14) for detecting the coating thickness on a surface or on sections of the surface of the process chambers (12) is arranged in at least one additional process chamber (12), wherein the measuring unit (14) is connectable to a control and evaluation unit.

2. The apparatus according to claim 1, wherein the measuring unit (14) comprises a coating thickness detection element (15), which has a sensor section, and the sensor section comprises a strain measuring strip and/or resistance measuring strip and/or capacitive sensor measuring strip and/or magnetic induction measuring strip.

3. The apparatus according to claim 1, wherein the measuring unit (14) comprises a carrier and seal section and a sensor section, wherein the sensor section can be non-destructively connected to and releasably combined with the carrier and seal section.

4. The apparatus according to claim 3, wherein the sensor section has a measuring tongue and an interface section, via which the connection to the carrier and seal section can be established.

5. The apparatus according to claim 1, wherein the measuring unit (14) has a transponder, with which data and/or signals can be transmitted from the control and evaluation unit wirelessly to a receiving station.

6. The apparatus according to claim 1, wherein the measuring unit (14) is arranged in an area of the at least one additional process chamber (12) which is accessible without having to open the entire vacuum system.

7. The apparatus according to claim 1, wherein the measuring unit (14) is arranged
in a bypass,
in a separable chamber or line section,
in a vacuum line (7) of the vacuum system,
in a supply line to the treatment chamber or
in a discharge line from the treatment chamber.

8. The apparatus according to claim 1, wherein the measuring unit (14) protrudes into a pipeline of the vacuum system.

9. The apparatus according to claim 2, wherein the measuring unit (14) comprises a carrier (23) for the coating thickness detection element (15) which is attached to a vacuum feedthrough (24), wherein the vacuum feedthrough (24) can be connected to a flange pipe (25) which opens into a hole (13) in the wall of the at least one additional process chamber (12), and wherein the coating thickness detection element (15) can be arranged in the area of the hole (13).

10. A method for monitoring surfaces in line paths of an apparatus for coating surfaces of objects according to claim 1, in which the measuring unit detects ACTUAL data of the coating thickness on a surface of the at least one additional process chamber as measured value and these ACTUAL data are forwarded to an evaluation device, in which these ACTUAL data are compared with NOMINAL data.

11. The method according to claim 10, in which the comparison of the ACTUAL data with the NOMINAL data is effected continuously or sequentially.

12. The method according to claim 10, in which in the case of predetermined configurations a signal with which a message, in particular a fault report or a warning message, is generated is produced when the ACTUAL data and the NOMINAL data are compared.

13. The method according to one of claim 10, wherein maintenance and/or shutdown times are predicted depending on the gradient of the measured value over time.

14. The method according to one of claim 10, wherein measurements are taken at several locations and messages about the need for maintenance and/or cleaning are notified by section and/or a shutdown is predicted.

15. The method according to one of claim 10, wherein the measuring unit, in particular the sensor section, is removed and is evaluated outside the apparatus for coating surfaces of objects.
